(19) United States
(12) Patent Application Publication
(10) Pub. No.: US 2023/0163246 A1
(43) Pub. Date: May 25, 2023

(54) DISPLAY DEVICE AND METHOD OF MANUFACTURING THE SAME

(71) Applicant: Samsung Display Co., LTD., Yongin-si (KR)

(72) Inventors: Dong Hyun LEE, Yongin-si (KR); Jae Hak LEE, Yongin-si (KR); Jun Young LEE, Yongin-si (KR)

(73) Assignee: Samsung Display Co., LTD., Yongin-si (KR)

(21) Appl. No.: 17/883,015

(22) Filed: Aug. 8, 2022

(30) Foreign Application Priority Data
Nov. 22, 2021 (KR) 10-2021-0161663

(51) Int. Cl. H01L 33/44; H01L 33/62; H01L 33/58; H01L 33/50; H01L 33/00; H01L 33/10

(52) U.S. Cl. CPC H01L 33/44; H01L 33/62; H01L 33/58; H01L 33/505; H01L 33/005; H01L 33/10; H01L 2933/0025; H01L 2933/0058

(57) ABSTRACT

A display device includes a display panel. The display panel includes a display area including pixels and a non-display area adjacent to at least a side of the display area. A circuit board is bonded to at least a surface of the display panel that overlaps the non-display area in a plan view, the circuit board being electrically connected to the pixels. An optical layer is disposed on the display panel. The optical layer includes a first region having a first thickness and a second region having a second thickness less than the first thickness of the first region of the optical layer. The second region of the optical layer overlaps the bonded portion of the circuit board in a plan view.

### CROSS REFERENCE TO RELATED APPLICATION(S)

This application claims priority to and benefits of Korean Patent Application No. 10-2021-0161663 under 35 U.S.C. § 119 filed on Nov. 22, 2021 in the Korean Intellectual Property Office, the entire contents of which are incorporated herein by reference.

### BACKGROUND

### 1. Technical Field

The disclosure relates to a display device and a method of manufacturing the same.

### 2. Description of the Related Art

As interest in information display increases and the demand to use portable information media increases, the demand for and commercialization of a display device are of current focus.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object of the disclosure is to provide a display device having improved reliability and a method of manufacturing the same.

Objects of the disclosure are not limited to the objects described above, and other technical objects will be clearly understood by those skilled in the art from the following description.

According to embodiments, a display device may include a display panel including pixels disposed in a display area and a non-display area adjacent to at least a side of the display area; a circuit board bonded to at least a surface of the display panel that overlaps the non-display area in a plan view, the circuit board being electrically connected to the pixels; and an optical layer disposed on the display panel. The optical layer may include a first region having a first thickness; and a second region having a second thickness less than the first thickness of the first region of the optical layer. The second region of the optical layer overlaps the bonded portion of the circuit board in a plan view.

The display device may further include a light blocking pattern disposed on a surface of the optical layer facing the circuit board in the second region of the optical layer.

The light blocking pattern may be at least one of a printed light blocking pattern, painted light blocking pattern, and anodized light blocking pattern.

The light blocking pattern may include at least one of a ceramic, a metal, an organic layer, and an inorganic layer.

A surface of the optical layer facing the circuit board in the second region of the optical layer may include a step.

The step of the optical layer may be a lasered portion or an etched portion of the second region of the optical layer.

The optical layer may include an anti-reflection layer; a support layer disposed below the anti-reflection layer that supports the anti-reflection layer; and an adhesive layer disposed below the support layer, and the adhesive layer may be removed in the second region of the optical layer.

A portion of the support layer may be removed in the second region of the optical layer.

The optical layer may include a reinforcing layer disposed below the support layer in the second region of the optical layer.

The reinforcing layer may be a hard-coated reinforcing layer and may absorb an external impact applied to the optical layer.

The display device may further include a protective layer disposed between the circuit board and the second region of the optical layer and covering a portion of the circuit board and the display panel.

The protective layer may include a resin between the circuit board and the second region of the optical layer.

The display device may further include a reflective layer disposed between the optical layer and the protective layer in the second region of the optical layer.

The protective layer may protrude outward from the second region of the optical layer in a plan view.

The second region of the optical layer may protrude outward from the display panel in a plan view.

The display panel may include a display element layer including a light emitting element; and a light conversion pattern layer disposed on the display element layer and changing a wavelength of light emitted from the light emitting element using a quantum dot, and the light conversion pattern layer may be formed through a successive process on a base surface provided by the display element layer.

The light emitting element may include an inorganic light emitting diode.

A method of manufacturing a display device may include attaching an optical layer to a display panel to cover a circuit board bonded to at least a surface of the display panel; applying a resin solution between the optical layer and the display panel through a gap between the optical layer and the circuit board; and forming a protective layer between the optical layer and the circuit board by curing the resin solution. The optical layer may include a first region having a first thickness; and a second region having a second thickness less than the first thickness of the first region of the optical layer. The second region of the optical layer overlaps the bonded portion of the circuit board in a plan view.

The optical layer may include an anti-reflection layer; a support layer disposed below the anti-reflection layer to support the anti-reflection layer; and an adhesive layer disposed below the support layer, and the adhesive layer may be removed in the second region of the optical layer.

A portion of the support layer may be removed in the second region of the optical layer.

The details of other embodiments are included in the detailed description and drawings.

A display device according to embodiments of the disclosure may include an optical layer, the optical layer may be disposed to cover a display panel and a circuit board, and a thickness of a second region of the optical layer overlapping the circuit board may be relatively small. Accordingly, a step may not occur on an upper surface of the optical layer.

A protective layer may be filled in the entire space between the optical layer and the display panel through a gap between the second region of the optical layer and the circuit board, and thus external water, moisture, and the like may be blocked from proceeding to an inside of the display panel.

An effect according to embodiments is not limited by the contents described above, and more various effects are included in the specification.

### BRIEF DESCRIPTION OF THE DRAWINGS

The above and other features of the disclosure will become more apparent by describing in further detail embodiments thereof with reference to the accompanying drawings, in which:

FIG. 1 is a diagram schematically illustrating a display device according to embodiments of the disclosure;

FIG. 2 is a schematic exploded perspective view of the display device of FIG. 1;

FIG. 3 is a schematic plan view of the display device of FIG. 2;

FIG. 4 is a schematic cross-sectional view schematically illustrating a display panel included in the display device of FIG. 3;

FIG. 5 is a schematic cross-sectional view taken along line II—II′ of FIG. 3;

FIG. 6 is a schematic cross-sectional view illustrating an embodiment of the display panel of FIG. 4;

FIG. 7 is a schematic cross-sectional view illustrating an embodiment of a pixel circuit layer and a display element layer included in the display device of FIG. 6;

FIGS. 8 and 9 are schematic cross-sectional views illustrating an embodiment of a display module taken along line I˜I′ of FIG. 2;

FIGS. 10 and 11 are schematic diagrams illustrating a method of manufacturing an optical layer included in the display module of FIG. 8;

FIGS. 12A, 12B, and 12C are schematic diagrams illustrating a method of manufacturing the display module of FIG. 9;

FIGS. 13 and 14 are schematic cross-sectional views illustrating a comparative embodiment of a display module taken along line I˜I′ of FIG. 2;

FIGS. 15 and 16 are schematic diagrams illustrating an embodiment of the optical layer included in the display module of FIG. 8;

FIG. 17 is a schematic cross-sectional view illustrating an embodiment of the display module taken along line I˜I′ of FIG. 2; and

FIGS. 18A and 18B are schematic cross-sectional views illustrating an embodiment of the display module taken along line I˜I′ of FIG. 2.

### DETAILED DESCRIPTION OF THE EMBODIMENTS

The disclosure may be modified in various manners and have various forms. Therefore, embodiments will be illustrated in the drawings and will be described in detail in the specification. However, it should be understood that the disclosure is not intended to be limited to the disclosed embodiments, and the disclosure includes all modifications, equivalents, and substitutions within the spirit and technical scope of the disclosure.

Similar reference numerals are used for similar components in describing each drawing. In the accompanying drawings, the dimensions of the structures may be shown enlarged from the actual dimensions for the sake of clarity of the disclosure but are not limited thereto.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Where a portion of a layer, a layer, an area, a plate, or the like is referred to as being “on” another portion, it includes not only a case where the portion is “directly on” another portion, but also a case where there is further another portion between the portion and another portion.

In the specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and another portion.

For example, the spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The phrase “in a plan view” means viewing the object from the top, and the phrase “in a schematic cross-sectional view” means viewing a cross-section of which the object is vertically cut from the side.

Hereinafter, embodiments and other embodiments necessary for those skilled in the art to understand the disclosure will be described in detail with reference to the accompanying drawings. In the following description, the singular expressions include plural expressions unless the context clearly dictates otherwise. For example, as used herein, the singular forms, “a,” “an,” and “the” are intended to include the plural forms as well, unless the context clearly indicates otherwise.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

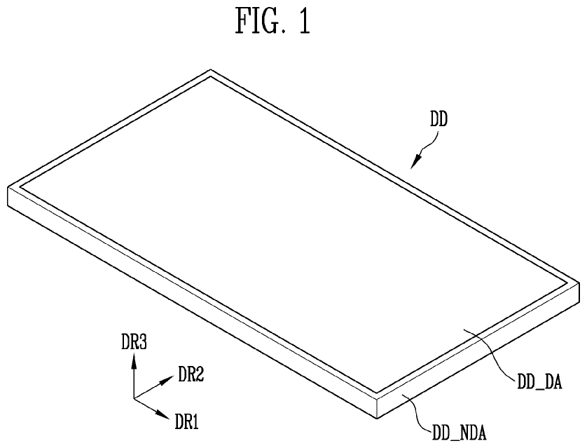

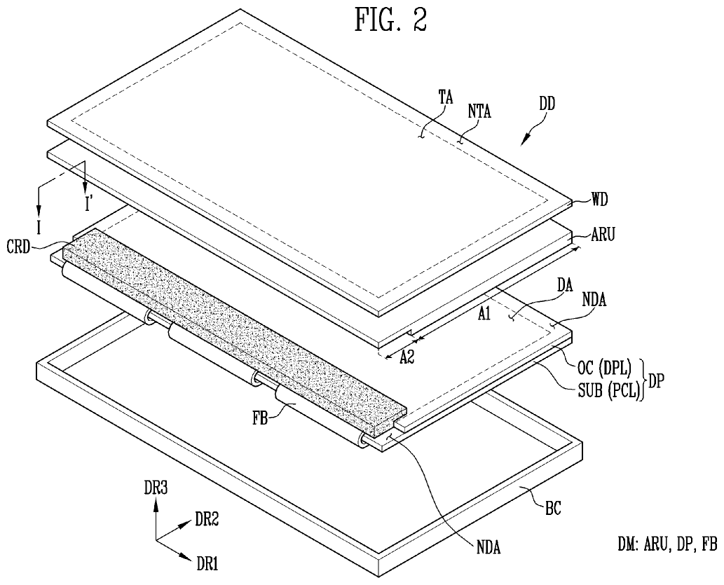

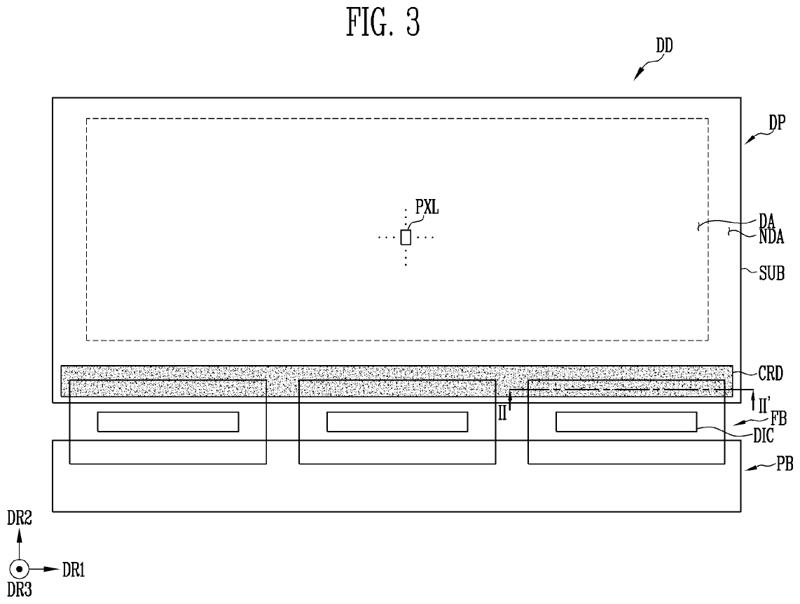

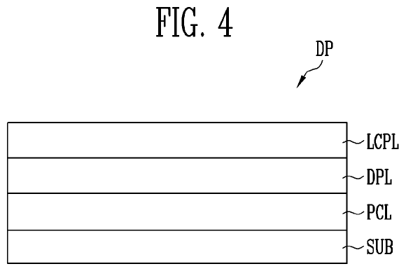

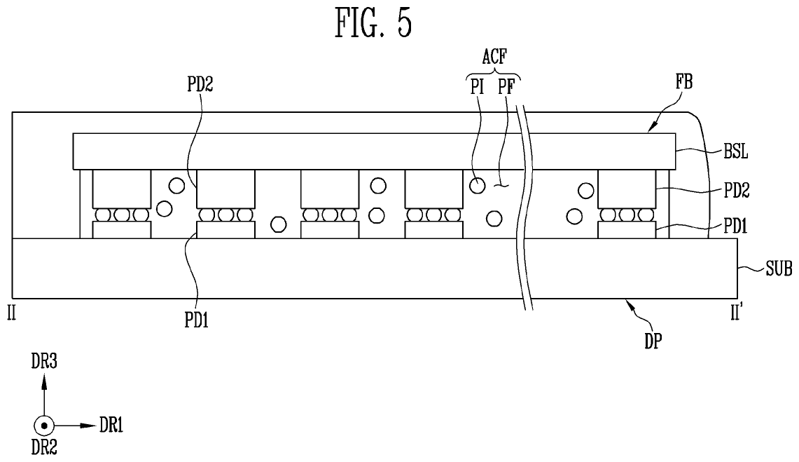

FIG. 1 is a diagram schematically illustrating a display device according to embodiments of the disclosure. FIG. 2 is a schematic exploded perspective view of the display device of FIG. 1. FIG. 3 is a schematic plan view of the display device of FIG. 2. FIG. 4 is a schematic cross-sectional view schematically illustrating a display panel included in the display device of FIG. 3. FIG. 5 is a schematic cross-sectional view taken along line II˜II′ of FIG. 3.

Referring to FIGS. 1 to 5, the display device DD may display an image through a display surface, for example, a display area DD_DA.

In case that the display device DD is an electronic device in which a display surface is applied to at least one surface or at least a surface, such as a smartphone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, or a wearable, the disclosure may be applied to the display device DD.

The display device DD may be provided in various shapes, and for example, the display device DD may be provided in a rectangular plate shape having two pairs of sides parallel to each other, but the disclosure is not limited thereto. In case that the display device DD is provided in the rectangular plate shape, one pair of sides of the two pairs of sides may be provided longer than the other pair of sides. In the drawing, the display device DD has an angled corner portion formed of a straight line, but the disclosure is not limited thereto. According to an embodiment, the display device DD provided in the rectangular plate shape may have a round shape at a corner portion where one long side and one short side contact each other.

In an embodiment of the disclosure, for convenience of description, the display device DD has a rectangular shape having a pair of long sides and a pair of short sides. An extension direction of the long sides is displayed as a first direction DR1, an extension direction of the short side is displayed as a second direction DR2, and a thickness direction of the display device DD (or a substrate SUB) is displayed as a third direction DR3.

In an embodiment of the disclosure, at least a portion of the display device DD may have flexibility, and the display device DD may be folded at a portion having flexibility.

The display device DD may include a display area DD_DA displaying an image and a non-display area DD_NDA provided on at least one side or a side of the display area DD_DA. The non-display area DD_NDA is an area in which an image is not displayed. However, the disclosure is not limited thereto. According to an embodiment, a shape of the display area DD_DA and a shape of the non-display area DD_NDA may be relatively designed.

According to an embodiment, the display device DD may include a sensing area and a non-sensing area. The display device DD may not only display an image through the sensing area, but may also sense a touch input performed on a display surface (or an input surface) or sense light incident from a front direction. The non-sensing area may surround the sensing area, but this is an example and may not be limited thereto. According to an embodiment, a partial area of the display area DD_DA may correspond to the sensing area.

The display device DD may include a window WD and a display module DM.

The window WD may be disposed on the display module DM to protect the display module DM from external impact and transmit an image provided from the display module DM through the transmission area TA. The window WD may include a transmissive area TA and a non-transmissive area NTA.

The transmissive area TA may have a shape corresponding to the display area DD_DA of the display device DD. For example, the image displayed on the display area DD_DA of the display device DD may be viewed from the outside through the transmissive area TA of the window WD.

The non-transmissive area NTA may have a shape corresponding to the non-display area DD_NDA of the display device DD. The non-transmissive area NTA may be an area having light transmittance relatively lower than that of the transmissive area TA. However, the disclosure is not limited thereto, and the non-transmissive area NTA may be omitted.

The window WD may have a multilayer structure selected from a glass substrate, a plastic film, and a plastic substrate. Such a multilayer structure may be formed through a successive process or an adhesion process using an adhesive layer. The entire or a portion of the window WD may have flexibility.

The display module DM may be disposed between the window WD and an accommodation member BC. The display module DM may include a display panel DP, a circuit board FB, and an optical layer ARU (or an optical film).

The display panel DP may display an image. As the display panel DP, a display panel for self-emission, such as an organic light emitting display panel (OLED panel) using an organic light emitting diode as a light emitting element, and an ultra-small light emitting diode display panel (micro-LED or nano-LED) using an ultra-small light emitting diode as a light emitting element, and a quantum dot organic light emitting display panel (QD OLED panel) using a quantum dot and an organic light emitting diode, may be used. As the display panel DP, a non-emission display panel, such as a liquid crystal display panel (LCD panel), an electro-phoretic display panel (EPD panel), and an electro-wetting display panel (EWD panel), may be used. In case that the non-emission display panel is used as the display panel DP, the display device DD may include a light emitting device that supplies light to the display panel DP.

The display panel DP may include the substrate SUB and pixels PXL provided on the substrate SUB.

The substrate SUB may be formed of one area or an area having an approximately rectangular shape. However, the number of areas provided on the substrate SUB may be different from the above-described example, and the shape of the substrate SUB may have a different shape according to the area provided on the substrate SUB.

The substrate SUB may be formed of an insulating material such as glass or resin. The substrate SUB may be formed of a material having flexibility to be bent or folded, and may have a single-layer structure or a multilayer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the material configuring the substrate SUB is not limited to the above-described embodiments.

The substrate SUB may include a display area DA and a non-display area NDA. The display area DA may be an area in which the pixels PXL are provided to display an image, and the non-display area NDA may be an area in which the pixels PXL are not provided and may be an area in which an image is not displayed. For convenience, only one pixel PXL is shown in FIG. 3, but pixels PXL may be provided in the display area DA of the substrate SUB.

The display area DA of the substrate SUB (or the display panel DP) may correspond to the display area DD_DA of the display device DD, and the non-display area NDA of the substrate SUB (or the display panel DP) may correspond to the non-display area DD_NDA of the display device DD. The non-display area NDA may correspond to a bezel area of the display device DD.

The non-display area NDA may be provided on at least one side or a side of the display area DA. The non-display area NDA may surround or may be adjacent to a circumference (or an edge) of the display area DA. In the non-display area NDA, a line unit connected to the pixels PXL and a driver connected to the line unit and driving the pixels PXL may be provided.

The line unit may electrically connect the driver and the pixels PXL. The line unit may provide a signal to each pixel PXL and may be a fan-out line connected to signal lines connected to each pixel PXL, for example, a scan line, a data line, and the like within the spirit and the scope of the disclosure.

First pads PD1 may be positioned on one surface or on a surface of the substrate SUB. The first pads PD1 may correspond to the non-display area NDA.

The pixels PXL may be provided in the display area DA of the substrate SUB. Each of the pixels PXL may be a minimum unit for displaying an image. The pixels PXL may include a light emitting element emitting white light and/or color light. Each of the pixels PXL may emit any one color among red, green, and blue, but is not limited thereto, and may emit cyan, magenta, yellow, or the like within the spirit and the scope of the disclosure.

The pixels PXL may be arranged (or disposed) in a matrix form along a row extending in the first direction DR1 and a column extending in the second direction DR2 crossing or intersecting the first direction DR1. However, an arrangement form of the pixels PXL is not particularly limited, and the pixels PXL may be arranged in various forms. The pixels PXL have a rectangular shape in the drawing, but the disclosure is not limited thereto, and the pixels PXL may be modified into various shapes. In case that pixels PXL are provided, the pixels PXL may be provided to have different areas (or sizes). For example, in a case of pixels PXL having different colors of emitted light, the pixels PXL may be provided in different areas (or sizes) or in different shapes for each color.

The driver may control driving of the pixel PXL by providing a signal and power to each pixel PXL through the line unit.

As shown in FIG. 4, the display panel DP may include a pixel circuit layer PCL, a display element layer DPL, and a light conversion pattern layer LCPL.

The pixel circuit layer PCL may be provided on the substrate SUB and may include transistors and signal lines connected to the transistor. For example, each transistor may have a form in which a semiconductor layer, a gate electrode, a first terminal, and a second terminal may be sequentially stacked with an insulating layer interposed therebetween. The semiconductor layer may include amorphous silicon, poly silicon, low temperature poly silicon, and an organic semiconductor. The gate electrode, the first terminal, and the second terminal may include one of aluminum (Al), copper (Cu), titanium (Ti), and molybdenum (Mo), but the disclosure is not limited thereto. The pixel circuit layer PCL may include one or more insulating layers.

The display element layer DPL may be disposed on the pixel circuit layer PCL. The display element layer DPL may include a light emitting element emitting light. The light emitting element may be, for example, an organic light emitting diode, but the disclosure is not limited thereto. According to an embodiment, the light emitting element may be an inorganic light emitting element including an inorganic light emitting material or a light emitting element that emits light by changing a wavelength of light emitted using a quantum dot.

The light conversion pattern layer LCPL may be disposed on the display element layer DPL. The light conversion pattern layer LCPL may change a wavelength (or a color) of light emitted from the display element layer DPL by using a quantum dot, and may selectively transmit light of a specific or given wavelength (or a specific or given color) by using a color filter. The light conversion pattern layer LCPL may be formed through a successive process on a base surface provided by the display element layer DPL.

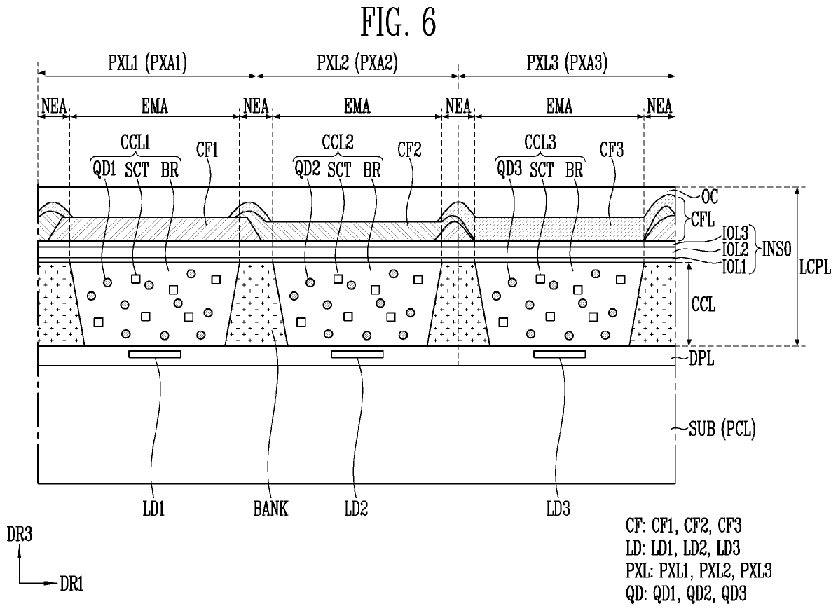

As will be described later with reference to FIG. 6, an overcoat layer OC may configure an uppermost layer of the display panel DP. The overcoat layer OC may have a form of an encapsulation layer formed of a multilayer. The overcoat layer OC may include an inorganic layer and/or an organic layer. For example, the overcoat layer OC may have a form in which an inorganic layer, an organic layer, and an inorganic layer may be sequentially stacked each other. The overcoat layer OC may prevent external air and moisture from penetrating into the display element layer DPL and the pixel circuit layer PCL.

A touch sensor (not shown) may be disposed between the display panel DP and the optical layer ARU. The touch sensor may be disposed on or directly disposed on a surface through which an image is emitted from the display panel DP to receive a user's touch input.

The circuit board FB may be connected to one end or an end (or one side surface or a side surface) of the display panel DP to provide a driving signal and a voltage to the display panel DP. For example, the driving signal may be a signal for displaying an image from the display panel DP, and the voltage may be a driving voltage necessary for driving the display panel DP. The circuit board FB may be provided as a flexible printed circuit board (FPCB). As shown in FIG. 2, the circuit board FB may be folded along one side surface or a side surface of the display panel DP and positioned on a rear surface of the display panel DP.

The circuit board FB may process various signals input from the printed circuit board PB and output the processed various signals to the display panel DP. To this end, the circuit board FB may be attached each of to the display panel DP and the printed circuit board PB. For example, one end or an end (or the one side surface or a side surface) of the circuit board FB may be bonded to the display panel DP by a conductive adhesive member ACF, and another end (or another side surface) of the circuit board FB facing the one end or an end may be bonded to the printed circuit board PB by another conductive adhesive member (not shown). The conductive adhesive member ACF and the other conductive adhesive member may include an anisotropic conductive film.

The conductive adhesive member ACF may include conductive particles PI formed in an adhesive film PF having an adhesive property. The conductive particles PI may electrically connect first pads PD1 of the display panel DP and second pads PD2 of the circuit board FB. Accordingly, signals or a voltage of driving power transferred to the second pads PD2 through a driver DIC mounted on the circuit board FB may be transferred to the first pads PD1 of the display panel DP through the conductive adhesive member ACF.

The first pads PD1 may be provided in a pad area positioned in the non-display area NDA of the substrate SUB at a preset distance. The second pads PD2 may be provided on a base layer BSL of the circuit board FB at a preset distance.

The driver DIC may be positioned on the circuit board FB. The driver DIC may be an integrated circuit (IC). The driver DIC may receive driving signals output from the printed circuit board PB, and may output a signal, a driving voltage (or driving power), and the like to be provided to the pixels PXL, based on the received driving signals. The above-described signals and driving voltage may be transferred to the first pads PD1 on the display panel DP through the second pads PD2 on the circuit board FB.

In the above-described embodiment, the driver DIC is disposed on the circuit board FB, but the disclosure is not limited thereto, and according to an embodiment, the driver DIC may be disposed (or mounted) on the substrate SUB of the display panel DP.

The printed circuit board PB may generate overall driving signals and power signals necessary for driving the display panel DP and provide the driving signals and power signals to the display panel DP. The printed circuit board PB may include a pad (not shown). The pad may be electrically connected to the pads of the circuit board FB. As a result, the driving signals and the power signals may be transferred from the printed circuit board PB to the driver DIC through the circuit board FB.

The printed circuit board PB may be configured in various forms. For example, the printed circuit board PB may be configured by stacking at least one layer or a layer of copper foil on one surface or on a surface or both surfaces of a base substrate formed of an epoxy resin or the like, and may be configured by stacking at least one layer or a layer of copper foil on one surface or a surface or both surfaces of a plastic film having flexibility. The printed circuit board PB may be formed in a multilayer structure in which a copper foil is formed inside of the base substrate.

The optical layer ARU may be disposed on the display panel DP and the circuit board FB. The optical layer ARU may reduce external light reflection. The optical layer ARU may be an anti-reflection layer including a polarization film and/or a retardation film. The number of retardation films and a retardation length (λ/4 or λ/2) of the retardation film may be determined according to an operation principle of the optical layer ARU. According to an embodiment, the optical layer ARU may include color filters.

In an embodiment, the optical layer ARU may include a first area A1 (or a first portion) and a second area A2 (or a second portion). The first area A1 may have a first thickness and may overlap the display area DA of the display panel DP in the third direction DR3. The second area A2 may have a second thickness less than the first thickness and overlap the non-display area NDA of the display panel DP in the third direction DR3 or overlap the circuit board FB (or the pad area of the display panel DP connected to the circuit board FB). Light transmittance in the second area A2 may be lower than that in the first area A1. A more detailed configuration of the optical layer ARU is described later with reference to FIGS. 8 to 11.

The accommodation member BC may be coupled or connected to the window WD. The accommodation member BC may provide a rear surface of the display device DD and may be coupled or connected to the window WD to define an internal space. The accommodation member BC may include a material having a relatively high rigidity. For example, the accommodation member BC may include frames and/or plates formed of glass, plastic, and metal. The accommodation member BC may stably protect configurations of the display device DD accommodated in the internal space from external impact. The accommodation member BC may include a material having high rigidity, but the disclosure is not limited thereto, and the accommodation member BC may include a flexible material. Although not shown, the display device DD according to an embodiment of the disclosure may have a characteristic in which the display device DD may be folded or bent. As a result, configurations included in the display device DD may also have a flexible property.

In an embodiment, the display device DD (or the display module DM) may further include an upper protective layer CRD (a protective layer, or a protective unit) that covers or overlaps one side surface or a side surface of each of the circuit board FB and the display panel DP.

The upper protective layer CRD may cover or overlap one side surface or a side surface of each of the circuit board FB and the display panel DP to prevent corrosion or the like of pads of each of the circuit board FB and the display panel DP. The upper protective layer CRD may cover or overlap one side surface or a side surface of each of the circuit board FB and the display panel DP to block external water, moisture, or the like from flowing into the pixels PXL. The upper protective layer CRD may further firmly couple or connect the circuit board FB and the display panel DP bonded to each other.

In an embodiment, the upper protective layer CRD may be formed of a resin. For example, the upper protective layer CRD may be formed of a thermosetting resin including a thermal polymerization initiator that initiates a curing reaction by heat. According to an embodiment, the upper protective layer CRD may be formed of a light-curable resin including a photopolymerization initiator that is crosslinked and cured by light such as ultraviolet light or infrared light. According to an embodiment, the upper protective layer CRD may include a light blocking material. Visibility of the circuit board FB positioned under or below the upper protective layer CRD may be more prevented.

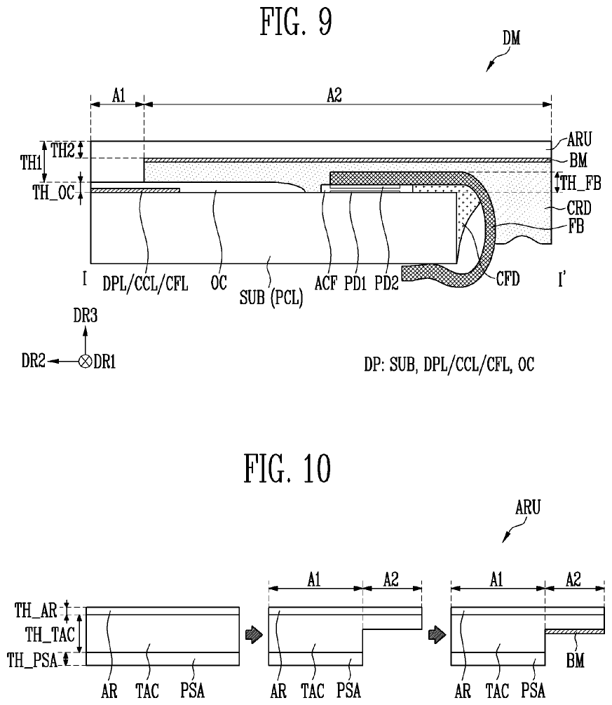

In an embodiment, the upper protective layer CRD may partially overlap the overcoat layer OC of the display panel DP in the third direction DR3. The upper protective layer CRD may be positioned to correspond to the second area A2 of the optical layer ARU. A disposition between the upper protective layer CRD and the second area A2 of the optical layer ARU is described later with reference to FIGS. 8 and 9.

FIG. 6 is a schematic cross-sectional view illustrating an embodiment of the display panel of FIG. 4. In FIG. 6, the display panel DP is shown based on the display area DA.

Referring to FIGS. 3, 4, and 6, a first pixel PXL1, a second pixel PXL2, and a third pixel PXL3 may be disposed on the substrate SUB. The first to third pixels PXL1, PXL2, and PXL3 may configure one unit pixel, but the disclosure is not limited thereto.

According to an embodiment, the first, second, and third pixels PXL1, PXL2, and PXL3 may emit light in different colors. For example, the first pixel PXL1 may be a red pixel emitting red light, the second pixel PXL2 may be a green pixel emitting green light, and the third pixel PXL3 may be a blue pixel emitting blue light. However, the color, type, number, and/or the like of pixels configuring the unit pixel are/is not particularly limited, and, for example, the color of light emitted by each of the pixels may be variously changed. According to an embodiment, the first, second, and third pixels PXL1, PXL2, and PXL3 may emit light in the same color. For example, each of the first to third pixels PXL1, PXL2, and PXL3 may be a blue pixel emitting blue light.

In an embodiment of the disclosure, unless otherwise specified, “formed and/or provided on the same layer” may mean formed in the same process, and “formed and/or provided on different layers” may mean formed in different processes.

The pixel circuit layer PCL and the display element layer DPL may be disposed on the substrate SUB. For convenience of description, the pixel circuit layer PCL is shown together with the substrate SUB, but as described with reference to FIG. 4, the pixel circuit layer PCL may be disposed between the substrate SUB and the display element layer DPL.

The display element layer DPL may include a light emitting element LD provided in each emission area EMA. For example, a first light emitting element LD1 may be provided in a first pixel area PXA1, a second light emitting element LD2 may be provided in a second pixel area PXA2, and a third light emitting element LD3 may be provided in a third pixel area PXA3.

The light emitting element LD may be configured of an organic light emitting diode, or an inorganic light emitting diode such as a quantum dot light emitting diode. In an embodiment, the light emitting element LD may be an ultra-small light emitting diode, for example, having a size as small as a nano scale to a micro scale, using a material of an inorganic crystal structure. The light emitting elements LD may be connected to each other in parallel and/or in series with the light emitting element LD disposed adjacently in each pixel PXL, but the disclosure is not limited thereto. The light emitting element LD may configure a light source of each pixel PXL. In other words, each pixel PXL may include at least one light emitting element LD driven by a signal (for example, a scan signal and a data signal) and/or power (for example, first driving power and second driving power).

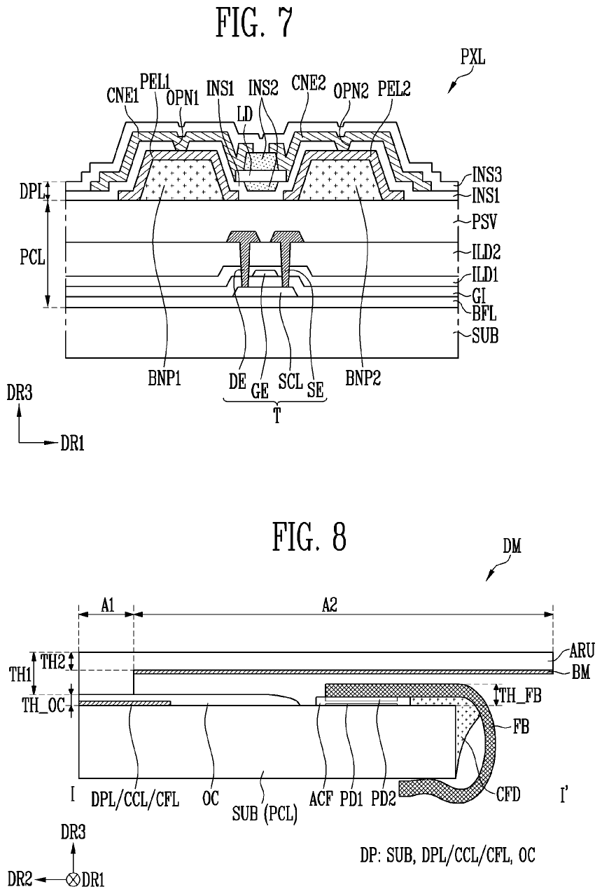

A detailed configuration of the pixel circuit layer PCL and the display element layer DPL is described later with reference to FIG. 7.

The light conversion pattern layer LCPL may include a color conversion layer CCL, an insulating layer INS0 (or a refractive index conversion layer), a color filter layer CFL (or a color filter CF), and an overcoat layer OC.

The color conversion layer CCL may include a bank BANK and first, second, and third color conversion patterns CCL1, CCL2, and CCL3 (or first, second, and third color conversion layers).

The bank BANK may be disposed on the display element layer DPL.

The bank BANK may be positioned in a non-emission area NEA of the first to third pixels PXL1, PXL2, and PXL3. The bank BANK may be formed between the first to third pixels PXL1, PXL2, and PXL3 to surround each emission EMA, and may define each emission area EMA of each of the first to third pixels PXL1, PXL2, and PXL3. The bank BANK may prevent a solution for forming the first, second, and third color conversion patterns CCL1, CCL2, and CCL3 in the emission area EMA from flowing into the emission area EMA of an adjacent pixel, or may function as a dam structure that controls an amount of solution to be supplied to each emission area EMA.

An opening for exposing the display element layer DPL may be formed in the bank BANK to correspond to the emission area EMA.

The first, second, and third color conversion patterns CCL1, CCL2, and CCL3 may be disposed in each opening of the bank BANK.

The first, second, and third color conversion patterns CCL1, CCL2, and CCL3 may include a base resin BR, color conversion particles QD, and light scattering particles SCT.

The base resin BR may have high light transmittance and an excellent dispersion characteristic for the color conversion particles QD. For example, the base resin BR may include an organic material such as an epoxy-based resin, an acryl-based resin, a cardo-based resin, or an imide-based resin.

The color conversion particles QD may convert light of a color emitted from the light emitting element LD disposed in one pixel into light of a specific or given color. For example, in case that the first pixel PXL1 is a red pixel, the first color conversion layer CCL1 may include first color conversion particles QD1 of a red quantum dot converting light emitted from the first light emitting element LD1 into red light. As another example, in case that the second pixel PXL2 is a green pixel, the second color conversion layer CCL2 may include second color conversion particles QD2 of a green quantum dot converting light emitted from the second light emitting element LD2 into green light. As a further example, in case that the third pixel PXL3 is a blue pixel, the third color conversion layer CCL3 may include third color conversion particles QD3 of a blue quantum dot converting light emitted from the third light emitting device LD3 into blue light. For example, in case that the third light emitting element LD3 emits blue light, the third color conversion layer CCL3 may not include the third color conversion particles QD3.

The light scattering particles SCT may have a refractive index different from that of the base resin BR and form an optical interface with the base resin BR. The light scattering particles SCT may be metal oxide particles or organic particles. According to an embodiment, the light scattering particles SCT may be omitted.

The insulating layer INS0 may be disposed on the color conversion layer CCL. The insulating layer INS0 may be entirely disposed on the substrate so as to cover or overlap the color conversion layer CCL (for example, the bank BANK and the first, second, and third color conversion patterns CCL1, CCL2, and CCL3).

The insulating layer INS0 may include at least three insulating layers, and may recycle light (for example, light proceeding in an oblique direction) emitted from the color conversion layer CCL using a refractive index difference (or total reflection due to the refractive index difference) between the three insulating layers. For example, the light totally reflected by the insulating layer INS0 may be reflected again in the third direction DR3 by the display element layer DPL (or an electrode included in the display element layer DPL and having a specific or given reflectance), or may be scattered in the third direction DR3 by the color conversion layer CCL (for example, the light scattering particle SCT). Therefore, efficiency (external quantum efficiency, or light output efficiency) of light finally emitted from the pixel PXL through the insulating layer INS0 or an emission luminance of the pixel PXL may be improved.

In embodiments, the insulating layer INS0 may include a first inorganic layer IOL1 (or a first dense film), a second inorganic layer IOL2 (or a low refractive film), and a third inorganic layer IOL3 (or a second dense film) sequentially stacked on the color conversion layer CCL.

The first inorganic layer IOL1 may be disposed on the color conversion layer CCL, and may prevent moisture (or a solution used in a subsequent process) from penetrating into the color conversion layer CCL thereunder. The second inorganic layer IOL2 may be disposed on the first inorganic layer IOL1, and may totally reflect the light (for example, the light proceeding in an oblique direction) emitted from the color conversion layer CCL using a refractive index difference with the first inorganic layer IOL1. The third inorganic layer IOL3 may be disposed on the second inorganic layer IOL2 and may improve adhesion force between the second inorganic layer IOL2 and the color filter layer CFL thereon.

The color filter layer CFL may be disposed on the insulating layer INS0.

The color filter layer CFL may include a color filter material that selectively transmits light of a specific or given color converted by the color conversion layer CCL. The color filter layer CFL may include a red color filter, a green color filter, and a blue color filter. For example, in case that the first pixel PXL1 is a red pixel, a first color filter CF1 that transmits red light may be disposed on the first pixel PXL1. In case that the second pixel PXL2 is a green pixel, a second color filter CF2 that transmits green light may be disposed on the second pixel PXL2. In case that the third pixel PXL3 is a blue pixel, a third color filter CF3 that transmits blue light may be disposed on the third pixel PXL3.

The overcoat layer OC may be disposed on the color filter layer CFL. The overcoat layer OC may be entirely disposed on the substrate SUB to cover or overlap a lower configuration, and may encapsulate the display area DA of the display panel DP (refer to FIG. 2).

FIG. 7 is a schematic cross-sectional view illustrating an embodiment of the pixel circuit layer and the display element layer included in the display device of FIG. 6. In FIG. 7, one pixel PXL is simplified, such as showing each electrode as a single-layer electrode and each insulating layer as only a single-layer insulating layer, but the disclosure is not limited thereto.

In an embodiment of the disclosure, “connection” between two configurations may mean that both an electrical connection and a physical connection are used inclusively.

Referring to FIGS. 3, 4, 6, and 7, each pixel PXL may include the pixel circuit layer PCL and the display element layer DPL disposed on the substrate SUB.

For convenience, the pixel circuit layer PCL is described first, and the display element layer DPL is described.

The pixel circuit layer PCL may include a buffer layer BFL, a transistor T, and a protective layer PSV.

The buffer may be provided and/or formed on the substrate SUB, and may prevent an impurity from diffusing into the transistor T. The buffer layer BFL may be an inorganic insulating layer including an inorganic material. The buffer layer BFL may include at least one of a metal oxide such as silicon nitride (SiNₓ), silicon oxide (SiOₓ), silicon oxynitride (SiOₓN_{y}), or aluminum oxide (AlOₓ). The buffer layer BFL may be provided as a single layer, or may be provided as a multilayer of at least a double layer. In case that the buffer layer BFL is provided as the multilayer, each layer may be formed of a same material or a similar material or different materials. The buffer layer BFL may be omitted according to a material, a process condition, and the like of the substrate SUB.

The transistor T may be a driving transistor that controls a driving current provided to the light emitting element LD. However, the disclosure is not limited thereto, and the transistor T may be a switching transistor that transfers a signal to the driving transistor or performs another function in addition to the driving transistor.

The transistor T may include a semiconductor pattern SCL, a gate electrode GE, a first terminal SE, and a second terminal DE. The first terminal SE may be one of a source electrode and a drain electrode, and the second terminal DE may be the other electrode. For example, in case that the first terminal SE is a source electrode, the second terminal DE may be a drain electrode.

The semiconductor pattern SCL may be provided and/or formed on the buffer layer BFL. The semiconductor pattern SCL may include a first contact region contacting the first terminal SE and a second contact region contacting the second terminal DE. A region between the first contact region and the second contact region may be a channel region. The channel region may overlap the gate electrode GE of the corresponding transistor T. The semiconductor pattern SCL may be a semiconductor pattern formed of amorphous silicon, poly silicon, low temperature poly silicon, an oxide semiconductor, an organic semiconductor, or the like within the spirit and the scope of the disclosure. The channel region is, for example, a semiconductor pattern that is not doped with an impurity, and may be an intrinsic semiconductor. The first contact region and the second contact region may be semiconductor patterns doped with an impurity.

The gate electrode GE may be provided and/or formed on a gate insulating layer GI to correspond to the channel region of the semiconductor pattern SCL. The gate electrode GE may be provided on the gate insulating layer GI and may overlap the channel region of the semiconductor pattern SCL. The gate electrode GE may be formed in a single layer of a material selected from a group consisting of copper (Cu), molybdenum (Mo), tungsten (W), aluminum neodymium (AlNd), titanium (Ti), aluminum (Al), silver (Ag), and an alloy thereof alone or a mixture thereof, or may be formed in a double layer or multilayer structure of a molybdenum (Mo), titanium (Ti), copper (Cu), aluminum (Al) or silver (Ag), which is a low-resistance material, to reduce a line resistance.

The gate insulating layer GI may be an inorganic insulating layer including an inorganic material. For example, the gate insulating layer GI may include at least one of a metal oxide such as silicon nitride (SiNₓ), silicon oxide (SiOₓ), silicon oxynitride (SiOₓN_{y}), and aluminum oxide (AlOₓ). However, the material of the gate insulating layer GI is not limited to the above-described embodiments, and various materials providing insulation to the gate insulating layer GI may be applied according to an embodiment. For example, the gate insulating layer GI may be formed of an organic insulating layer including an organic material. The gate insulating layer GI may be provided as a single layer, but may also be provided as a multilayer of at least a double layer.

Each of the first terminal SE and the second terminal DE may be provided and/or formed on the second interlayer insulating layer ILD2, and may be in contact with the first contact region and the second contact region of the semiconductor pattern SCL through a contact hole sequentially passing through the gate insulating layer GI and the first and second interlayer insulating layers ILD1 and ILD2. For example, the first terminal SE may be in contact with the first contact region of the semiconductor pattern SCL, and the second terminal DE may be in contact with the second contact region of the semiconductor pattern SCL. Each of the first and second terminals SE and DE may include a same material or a similar material as the gate electrode GE, or may include one or more materials selected from materials as a configuration material of the gate electrode GE.

The first interlayer insulating layer ILD1 may include a same material or a similar material as the gate insulating layer GI, or may include one or more materials selected from materials as a configuration material of the gate insulating layer GI.

The second interlayer insulating layer ILD2 may be provided and/or formed on the first interlayer insulating layer ILD1. The second interlayer insulating layer ILD2 may be an inorganic insulating layer including an inorganic material or an organic insulating layer including an organic material. According to an embodiment, the second interlayer insulating layer ILD2 may include a same material or a similar material as the first interlayer insulating layer ILD1, but the disclosure is not limited thereto. The second interlayer insulating layer ILD2 may be provided as a single layer, or may be provided as a multilayer of at least a double layer. According to an embodiment, the second interlayer insulating layer ILD2 may be omitted.

In the above-described embodiment, the first and second terminals SE and DE of the transistor T are separate electrodes electrically connected to the semiconductor pattern SCL through the contact hole sequentially passing through the gate insulating layer GI and the first and second interlayer insulating layers ILD1 and ILD2, but the disclosure is not limited thereto. According to an embodiment, the first terminal SE of the transistor T may be a first contact region adjacent to the channel region of the semiconductor pattern SCL, and the second terminal DE of the transistor T may be a second contact region adjacent to the channel region of the semiconductor pattern SCL. The second terminal DE of the transistor T may be electrically connected to the light emitting element LD of the pixel PXL through a separate connection means such as a bridge electrode.

The transistor T may be configured of a low temperature polysilicon thin film transistor (LTPS TFT), but the disclosure is not limited thereto. According to an embodiment, the transistors T may be configured of an oxide semiconductor thin film transistor. Although a case in which the transistor T is a thin film transistor of a top gate structure has been described as an example in the above-described embodiment, the disclosure is not limited thereto, and a structure of the transistor T may be variously changed. For example, the transistor T may be a thin film transistor having a bottom gate structure.

The pixel circuit layer PCL may further include a storage capacitor storing a voltage applied between a gate electrode and the first terminal SE (or the source electrode) of the transistor T, a driving voltage line providing a driving voltage to the transistor T (or the pixel PXL), and the like within the spirit and the scope of the disclosure.

The protective layer PSV may be provided and/or formed on the transistor T.

The protective layer PSV may be provided in a form including an organic insulating layer, an inorganic insulating layer, or an organic insulating layer disposed on an inorganic insulating layer. The inorganic insulating layer may include, for example, at least one of a metal oxide such as silicon oxide (SiOₓ), silicon nitride (SiNₓ), silicon oxynitride (SiOₓN_{y}), or aluminum oxide (AlOₓ). The organic insulating layer may include, for example, at least one of acrylic resin (polyacrylates resin), epoxy resin, phenolic resin, polyamides resin, polyimide resin, unsaturated polyesters resin, poly-phenylen ethers resin, poly-phenylene sulfides resin, and benzocyclobutene resin.

The display element layer DPL may be provided on the protective layer PSV.

The display element layer DPL may include first and second bank patterns BNP1 and BNP2, first and second pixel electrodes PEL1 and PEL2, the light emitting element LD, and first and second contact electrodes CNE1 and CNE2. The display element layer DPL may include first, second, and third insulating layers INS1, INS2, and INS3.

The first and second bank patterns BNP1 and BNP2 may be positioned in the emission area EMA (refer to FIG. 6) and may be spaced apart from each other. The first and second bank patterns BNP1 and BNP2 may be support members that support each of the first and second pixel electrodes BNP1 and BNP2 to change a surface profile (or a shape) of the third direction DR3 of each of the first and second pixel electrodes BNP1 and BNP2 so as to guide light emitted from the light emitting elements LD in an image display direction (for example, a front surface direction) of the display device. For example, the first and second bank patterns BNP1 and BNP2 may change the surface profile (or the shape) of each of the first and second pixel electrodes PEL1 and PEL2 in the third direction DR3.

The first and second bank patterns BNP1 and BNP2 may be provided and/or formed between the protective layer PSV and a corresponding electrode in the emission area of a corresponding pixel PXL. For example, the first bank pattern BNP1 may be provided and/or formed between the protective layer PSV and the first pixel electrode PEL1, and the second bank pattern BNP2 may be provided and/or formed between the protective layer PSV and the second pixel electrode PEL2.

The first and second bank patterns BNP1 and BNP2 may be an inorganic insulating layer including an inorganic material or an organic insulating layer including an organic material. According to an embodiment, the first and second bank patterns BNP1 and BNP2 may include a single organic insulating layer and/or a single inorganic insulating layer, but the disclosure is not limited thereto. According to an embodiment, the first and second bank patterns BNP1 and BNP2 may be provided in a form of a multilayer in which at least one organic insulating layer and at least one inorganic insulating layer may be stacked each other. However, the material of the first and second bank patterns BNP1 and BNP2 is not limited to the above-described embodiments, and according to an embodiment, the first bank pattern BNP1 may include a conductive material.

The first and second bank patterns BNP1 and BNP2 may have a trapezoidal-shaped cross-section in which a width becomes narrower from one surface or a surface (for example, an upper surface) of the protective layer PSV toward an upper portion along the third direction DR3, but the disclosure is not limited thereto. According to an embodiment, the first and second bank patterns BNP1 and BNP2 may include a curved surface having a cross-section of a semi-elliptical shape, a semi-circular shape (or a hemispherical shape). In case that viewed in a cross-section, the shape of the first and second bank patterns BNP1 and BNP2 is not limited to the above-described embodiments and may be variously changed within a range for improving efficiency of the light emitted from each of the light emitting elements LD. The first and second bank patterns BNP1 and BNP2 adjacent in the first direction DR1 may be disposed on a same surface of the protective layer PSV, and may have a same height (or thickness) in the third direction DR3.

In the above-described embodiment, the first and second bank patterns BNP1 and BNP2 are provided and/or formed on the protective layer PSV, and thus the first and second bank patterns BNP1 and BNP2 and the protective layer PSV are formed by different processes, but the disclosure is not limited thereto. According to an embodiment, the first and second bank patterns BNP1 and BNP2 and the protective layer PSV may be formed through a same process. The first and second bank patterns BNP1 and BNP2 may be one region or a region of the protective layer PSV.

The first and second pixel electrodes PEL1 and PEL2 may be provided and/or formed on the first and second bank patterns BNP1 and BNP2 corresponding thereto.

Each of the first and second pixel electrodes PEL1 and PEL2 may be formed of a material having a reflectance in order to allow the light emitted from the light emitting element LD to proceed in the image display direction of the display device. Each of the first and second pixel electrodes PEL1 and PEL2 may be formed of a conductive material having a reflectance. The conductive material may include an opaque metal advantageous for reflecting the light emitted from the light emitting element LD in the image display direction of the display device. The opaque metal may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. According to an embodiment, each of the first and second pixel electrodes PEL1 and PEL2 may include a transparent conductive material. The transparent conductive material may include a conductive oxide such as indium tin oxide (ITO), indium zinc oxide (IZO), zinc oxide (ZnOx), indium gallium zinc oxide (IGZO), or indium tin zinc oxide (ITZO), a conductive polymer such as poly(3,4-ethylenedioxythiophene) (PEDOT), and the like within the spirit and the scope of the disclosure.

In case that each of the first and second pixel electrodes PEL1 and PEL2 may include a transparent conductive material, a separate conductive layer formed of an opaque metal for reflecting the light emitted from the light emitting element LD in the image display direction of the display device may be added. However, the material of each of the first and second pixel electrodes PEL1 and PEL2 is not limited to the above-described materials.

Each of the first and second pixel electrodes PEL1 and PEL2 may be provided and/or formed as a single layer, but the disclosure is not limited thereto. According to an embodiment, each of the first and second pixel electrodes PEL1 and PEL2 may be provided and/or formed as a multilayer in which at least two or more materials among metals, alloys, conductive oxides, and conductive polymers may be stacked each other. Each of the first and second pixel electrodes PEL1 and PEL2 may be formed of a multilayer of a double or more layers to minimize distortion due to a signal delay in case that transferring a signal (or a voltage) to both ends of each of the light emitting elements LD. For example, each of the first and second pixel electrodes PEL1 and PEL2 may be formed in a multilayer in which indium tin oxide (ITO)/silver (Ag)/indium tin oxide (ITO) may be sequentially stacked each other.

According to an embodiment, the first pixel electrode PEL1 may be electrically connected to the transistor T through a first contact hole passing through the protective layer PSV, and the second pixel electrode PEL2 may be electrically connected to a driving voltage line of the pixel circuit layer PCL through a second contact hole passing through the protective layer PSV.

Each of the first pixel electrode PEL1 and the second pixel electrode PEL2 may receive an alignment signal (or alignment voltage) from a corresponding partial configuration of the pixel circuit layer PCL and may be used as an alignment electrode (or an alignment line) for alignment of the light emitting elements LD. For example, the first pixel electrode PEL1 may receive a first alignment signal (or a first alignment voltage) from a partial configuration of the pixel circuit layer PCL and may be used as a first alignment electrode (or a first alignment line), and the second pixel electrode PEL2 may receive a second alignment signal (or a second alignment voltage) from another configuration of the pixel circuit layer PCL and may be used as a second alignment electrode (or a second alignment line).

After the light emitting element LD is aligned in the pixel PXL, a portion of the first pixel electrode PEL1 positioned between adjacent pixels PXL may be removed to individually (or independently) drive the pixel PXL.

After the light emitting element LD is aligned, the first pixel electrode PEL1 and the second pixel electrode PEL2 may be used as driving electrodes for driving the light emitting elements LD.

The light emitting element LD may be an ultra-small light emitting diode, for example, having a size as small as a nano scale to a micro scale using a material of an inorganic crystal structure. For example, the light emitting element LD may include a first semiconductor layer, a second semiconductor layer, an active layer, and an insulating layer. The first semiconductor layer may include a semiconductor layer having a type, and the second semiconductor layer may include a semiconductor layer of a type different from that of the first semiconductor layer. For example, the first semiconductor layer may include an N-type semiconductor layer, and the second semiconductor layer may include a P-type semiconductor layer. The first semiconductor layer and the second semiconductor layer may include at least one semiconductor material among InAlGaN, GaN, AlGaN, InGaN, AlN, and InN. The active layer may be positioned between the first semiconductor layer and the second semiconductor layer, and may have a single or multiple quantum well structure. In case that an electric field greater than or equal to a voltage is applied to the both ends of the light emitting element LD, an electron-hole pair may be combined in the active layer and light may be emitted.

At least two to tens of light emitting elements LD may be arranged and/or provided in the emission area EMA, but the number of light emitting elements LD arranged and/or provided in the emission area EMA is not limited thereto. According to an embodiment, the number of light emitting elements LD arranged and/or provided in the emission area EMA may be variously changed.

Each of the light emitting elements LD may emit any one of color light and/or white light. In an embodiment, each of the light emitting elements LD may emit blue light of a short wavelength band, but the disclosure is not limited thereto.

The first insulating layer INS1 may be provided and/or formed on the first and second pixel electrodes PEL1 and PEL2.

The first insulating layer INS1 may include an inorganic insulating layer formed of an inorganic material or an organic insulating layer formed of an organic material. The first insulating layer INS1 may be formed of an inorganic insulating layer advantageous for protecting the light emitting element LD from the pixel circuit layer PCL of the pixel PXL. For example, the first insulating layer INS1 may include at least one of a metal oxide such as silicon nitride (SiNₓ), silicon oxide (SiOₓ), silicon oxynitride (SiOₓN_{y}), and aluminum oxide (AlOₓ), but the disclosure is not limited thereto. According to an embodiment, the first insulating layer INS1 may be formed of an organic insulating layer advantageous for planarizing a support surface of the light emitting elements LD.

The first insulating layer INS1 may include a first opening OPN1 exposing one region or a region of the first pixel electrode PEL1 and a second opening OPN2 exposing one region or a region of the second pixel electrode PEL2. The first insulating layer INS1 may cover or overlap remaining regions except for one region or a region of each of the first and second pixel electrodes PEL1 and PEL2 (for example, the regions corresponding to the first and second openings OPN1 and OPN2). The light emitting elements LD may be disposed (or aligned) on the first insulating layer INS1 between the first pixel electrode PEL1 and the second pixel electrode PEL2.

The second insulating layer INS2 (or a second insulating pattern) may be provided and/or formed on the light emitting element LD. The second insulating layer INS2 may be provided and/or formed on the light emitting element LD to partially cover or overlap an outer circumferential surface (or a surface) of the light emitting element LD. The active layer of the light emitting element LD may not be in contact with an external conductive material by the second insulating layer INS2. The second insulating layer INS2 may cover or overlap only a portion of the outer peripheral surface (or the surface) of the light emitting element LD to expose the both ends of the light emitting element LD to the outside. The second insulating layer INS2 may be formed as an insulating pattern independent of the pixel PXL, but the disclosure is not limited thereto.

The second insulating layer INS2 may be configured of a single layer or a multilayer, and may include an inorganic insulating layer including at least one inorganic material or an organic insulating layer including at least one organic material. According to a design condition or the like of the display device to which the light emitting element LD is applied, the second insulating layer INS2 may be formed of an inorganic insulating layer including an inorganic material or an organic insulating layer including an organic material. After the alignment of the light emitting element LD is completed in the pixel PXL, the second insulating layer INS2 may be formed on the light emitting element LD to prevent the light emitting element LD from being separated from an aligned position.

The first contact electrode CNE1 may be provided on the first pixel electrode PEL1 to be in contact with or to be connected to the first pixel electrode PEL1 through the first opening OPN1 of the first insulating layer INS1. According to an embodiment, in case that a capping layer (not shown) is disposed on the first pixel electrode PEL1, the first contact electrode CNE1 may be disposed on the capping layer and may be connected to the first pixel electrode PEL1 through the capping layer. The above-described capping layer may protect the first pixel electrode PEL1 from a defect or the like generated during a manufacturing process of the display device, and may further strengthen adhesion force between the first pixel electrode PEL1 and the pixel circuit layer PCL positioned thereunder. The capping layer may include a transparent conductive material (or substance) such as indium zinc oxide (IZO).

The first contact electrode CNE1 may be provided and/or formed on one end or an end of the light emitting element LD to be connected to the one end or an end of the light emitting element LD. Accordingly, the first pixel electrode PEL1 and the one end or an end of the light emitting element LD may be electrically connected to each other through the first contact electrode CNE1.

Similar to the first contact electrode CNE1, the second contact electrode CNE2 may be provided on the second pixel electrode PEL2 to be in contact with or to be connected to the second pixel electrode PEL2 through the second opening OPN2 of the first insulating layer INS1. According to an embodiment, in case that a capping layer is disposed on the second pixel electrode PEL2, the second contact electrode CNE2 may be disposed on the capping layer and may be connected to the second pixel electrode PEL2 through the capping layer. The second contact electrode CNE2 may be provided and/or formed on the other end of the light emitting element LD to be connected to the other end or another end of the light emitting element LD. Accordingly, the second pixel electrode PEL2 and the other end or another end of the light emitting element LD may be electrically connected to each other through the second contact electrode CNE2.

The first and second contact electrodes CNE1 and CNE2 may be formed of various transparent conductive materials to allow light emitted from the light emitting element LD and reflected by the first and second pixel electrodes PEL1 and PEL2 to proceed in the image display direction of the display device without loss. For example, the first and second contact electrodes CNE1 and CNE2 may include at least one of various transparent conductive materials (or substances) including indium tin oxide (ITO), indium zinc oxide (IZO), zinc oxide (ZnOₓ), indium gallium zinc oxide (IGZO), indium tin zinc oxide (ITZO), and the like, and may be configured to be substantially transparent or translucent to satisfy a light transmittance. However, the material of the first and second contact electrodes CNE1 and CNE2 is not limited to the above-described embodiment. According to an embodiment, the first and second contact electrodes CNE1 and CNE2 may be formed of various opaque conductive materials (or substances). The first and second contact electrodes CNE1 and CNE2 may be formed of a single layer or a multilayer.

A shape of the first and second contact electrodes CNE1 and CNE2 may not be limited to a specific shape, and may be variously changed within a range electrically and stably connected to the light emitting element LD. The shape of the first and second contact electrodes CNE1 and CNE2 may be variously changed in consideration of a connection relationship with electrodes disposed thereunder.

The first and second contact electrodes CNE1 and CNE2 may be disposed to be spaced apart from each other in the first direction DR1. For example, the first contact electrode CNE1 and the second contact electrode CNE2 may be disposed to be spaced apart from each other with a distance therebetween on the second insulating layer INS2. The first contact electrode CNE1 and the second contact electrode CNE2 may be provided on a same layer and may be formed through a same process. However, the disclosure is not limited thereto, and according to an embodiment, the first and second contact electrodes CNE1 and CNE2 may be provided on different layers and may be formed through different processes.

The third insulating layer INS3 may be provided and/or formed on the first and second contact electrodes CNE1 and CNE2. The third insulating layer INS3 may be an inorganic insulating layer including an inorganic material or an organic insulating layer including an organic material. For example, the third insulating layer INS3 may have a structure in which at least one inorganic insulating layer or at least one organic insulating layer may be alternately stacked each other. The third insulating layer INS3 may entirely cover or overlap the display element layer DPL to prevent water, moisture, or the like from flowing into the display element layer DPL including the light emitting elements LD from the outside.

FIGS. 8 and 9 are schematic cross-sectional views illustrating an embodiment of a display module taken along line I˜I′ of FIG. 2.

Referring to FIGS. 1 to 9, the display module DM may include the display panel DP, the circuit board FB, and the optical layer ARU.

The display panel DP may include the substrate SUB, the display element layer DPL (the pixel circuit layer PCL, the color conversion layer CCL, and the color filter layer CFL) including the pixels PXL (refer to FIGS. 3 and 7) provided on the substrate SUB, and the overcoat layer OC covering or overlapping the display element layer DPL. The display panel DP may include the first pads PD1 positioned on one surface or a surface of the substrate SUB.

The overcoat layer OC may be a planarization layer that alleviates a step (or height difference) caused by configurations included in the display panel DP disposed thereunder. The overcoat layer OC may be a protective means that covers or overlaps the display panel DP to protect the pixels PXL. To this end, the overcoat layer OC may be formed of an organic insulating layer including an organic material. The organic insulating layer may include, for example, at least one of acrylic resin (polyacrylates resin), epoxy resin, phenolic resin, polyamides resin, polyimides resin, unsaturated polyesters resin, poly-phenylen ethers resin, poly-phenylene sulfides resin, and enzocyclobutene resin. However, the material of the overcoat layer OC is not limited to the above-described materials.

The circuit board FB may be disposed on one side or a side of the display panel DP so that one surface or a surface on which the second pads PD2 are positioned faces the first pads PD1. The second pads PD2 of the circuit board FB may be electrically connected to the first pads PD1 of the display panel DP through the conductive adhesive member ACF. The circuit board FB may be folded along one side or a side of the display module DM to be positioned on a rear surface of the display module DM. The circuit board FB may be electrically connected to the printed circuit board PB (refer to FIG. 3).

A lower protective layer CFD (a lower cover layer, or a lower protective member) may be disposed on a lower surface of the circuit board FB. The lower protective layer CFD may be partially positioned under or below the circuit board FB attached to one side or a side of the display panel DP to correspond to a bonding coupling portion of the circuit board FB and the display panel DP. The lower protective layer CFD may cover or overlap the bonding coupling portion of the circuit board FB and the display panel DP. The lower protective layer CFD may protect the bonding coupling portion and may block external water, moisture, and the like from flowing into the bonding coupling portion and proceeding to an inside of the display panel DP. The bonding coupling portion of the circuit board FB and the display panel DP may be a position where the second pads PD2 of the circuit board FB and the first pads PD1 of the display panel DP are mutually coupled or connected through the conductive adhesive member ACF.

The lower protective layer CFD may be formed of a resin. For example, the lower protective layer CFD may be formed of a thermosetting resin including a thermal polymerization initiator that initiates a curing reaction by heat. According to an embodiment, the lower protective layer CFD may be formed of a light-curable resin including a photopolymerization initiator that is crosslinked and cured by light such as ultraviolet light or infrared light.

The optical layer ARU may be provided on the display panel DP and the circuit board FB. The optical layer ARU may be an anti-reflection layer for preventing external light from being viewed. The optical layer ARU may cover or overlap the display panel DP and the circuit board FB. To this end, the optical layer ARU may protrude outward than (for example, in a direction opposite to the second direction DR2) the display panel DP (and the circuit board FB).

In embodiments, in an embodiment, the optical layer ARU may include the first area A1 and the second area A2. The first area A1 may have a first thickness TH1 and may overlap the overcoat layer OC of the display panel DP in the third direction DR3. The second area A2 may have a second thickness TH2 and may overlap the circuit board FB (or the first pads DP of the display panel DP connected to the circuit board FB) in the third direction DR3. The second thickness TH2 of the second area A2 may be less than the first thickness TH1 of the first area A1. As shown in FIG. 8, an upper surface of the optical layer ARU may be flat, and a step may be formed on a lower surface of the optical layer ARU. The lower surface of the optical layer ARU may face the circuit board FB.

In an embodiment, a difference between the first thickness TH1 and the second thickness TH2 may be greater than a difference between a thickness TH_FB of the circuit board FB and a thickness TH_OC of the overcoat layer OC. Here, the thickness TH_FB of the circuit board FB may be a thickness to an upper surface of the circuit board FB based on an upper surface of the substrate SUB, and the thickness TH_OC of the overcoat layer OC may be a thickness to an upper surface of the overcoat layer OC based on the upper surface the substrate SUB. For example, the thickness TH_FB of the circuit board FB may be in a range of about 50 μm to about 80 μm, the thickness TH_OC of the overcoat layer OC may be in a range of about 30 μm to about 50 μm, the first thickness TH1 may be in a range of about 90 μm to about 100 μm or about 92 μm, and the second thickness TH2 may be in a range of about 20 μm to about 50 μm. Since the difference between the first thickness TH1 and the second thickness TH2 is greater than the difference between the thickness TH_FB of the circuit board FB and the thickness TH_OC of the overcoat layer OC, the first area A1 may be in contact with the overcoat layer OC, and the second area A2 of the optical layer ARU may be spaced apart from the circuit board FB. As shown in FIG. 9, a resin (for example, the upper protective layer CRD) may be applied or filled in a space between the optical layer ARU and the display panel DP through a space formed in which the second area A2 of the optical layer ARU and the circuit board FB are spaced apart from each other.

A length (or a width) of the second area A2 of the optical layer ARU in the second direction DR2 may be in a range of about 3 mm to about 4 mm, or about 3.75 mm, but is not limited thereto.

In an embodiment, the optical layer ARU may further include a light blocking pattern BM disposed on a lower surface of the optical layer ARU in the second area A2 of the optical layer ARU. The light blocking pattern BM may be entirely disposed in the second area A2 of the optical layer ARU, and may prevent the circuit board FB (or the bonding coupling portion of the circuit board FB and the display panel DP) from being viewed.

In an embodiment, the light blocking pattern BM may include a light blocking material such as a black matrix. Due to the light blocking pattern BM, light transmittance in the second area A2 may be lower than that of the first area A1. The light blocking pattern BM may be formed of a ceramic, a metal, an organic layer, and/or an inorganic layer. The light blocking material may include, for example, a material based on carbon black, titanium black, iron sulfide, or the like, but the light blocking material is not limited thereto.

In an embodiment, the light blocking pattern BM may include a same material or a similar material as a configuration (for example, the bank (refer to FIG. 6) or a black matrix) positioned in the non-emission area NEA (refer to FIG. 6) (for example, the area in which light is not emitted in each pixel PXL) surrounding the emission area EMA (refer to FIG. 6) of the display panel DP to alleviate sense of difference between the bonding coupling portion of the circuit board FB and the display panel DP and the display area DA.

In an embodiment, the display module DM may further include the upper protective layer CRD (an upper cover layer, or an upper protective member).

As shown in FIG. 9, the upper protective layer CRD may be disposed under or below the second area A2 of the optical layer ARU, and may be partially positioned on the circuit board FB attached to one side surface or a side surface of the display panel DP to correspond to the bonding coupling portion of the display panel DP. The upper protective layer CRD may be filled between the circuit board FB and the second area A2 of the optical layer ARU to cover or overlap the bonding coupling portion of the circuit board FB and the display panel DP. The upper protective layer CRD may protect the bonding coupling portion and block external water, moisture, and the like from flowing into the bonding coupling portion and proceeding to the inside of the display panel DP, together with the lower protective layer CFD. The upper protective layer CRD may support the second area A2 of the optical layer ARU.

In an embodiment, the upper protective layer CRD may include a light blocking material to prevent the bonding coupling portion of the circuit board FB and the display panel DP from being viewed. The light blocking pattern BM of the optical layer ARU may be omitted.

The upper protective layer CRD may include a thermosetting resin including a light blocking material. According to an embodiment, the upper protective layer CRD may include a light-curable resin including a light blocking material. For example, the upper protective layer CRD may include a resin based on epoxy, acrylic, urethane, or the like including a black particle.

In an embodiment, the upper protective layer CRD may include a lower surface contacting the display panel DP and the circuit board FB and an upper surface facing the lower surface. The upper surface of the upper protective layer CRD may correspond to the second area A2 of the optical layer ARU and may be generally flat.

As described above, the optical layer ARU may include the first area A1 and the second area A2, and the second thickness TH2 of the second area A2 may be less than the first thickness TH1 of the first area A1. The light blocking pattern BM disposed in the second area A2 of the optical layer ARU may prevent the circuit board FB from being viewed. The upper protective layer CRD may be filled in the entire space between the optical layer ARU and the display panel DP through a gap between the second area A2 of the optical layer ARU and the circuit board FB. The upper protective layer CRD may cover or overlap the bonding coupling portion of the circuit board FB and the display panel DP, and thus external water, moisture, or the like may be blocked from flowing into the bonding coupling portion. According to an embodiment, the upper protective layer CRD may include a light blocking material and may prevent the circuit board FB from being viewed, together with the light blocking pattern BM. The light blocking pattern BM (and/or the upper protective layer CRD) may include a same material or a similar material as a configuration (for example, a black matrix) positioned in the non-emission area of the display panel DP, to alleviate sense of difference between the bonding coupling portion of the circuit board FB and the display panel DP and the display area DA.

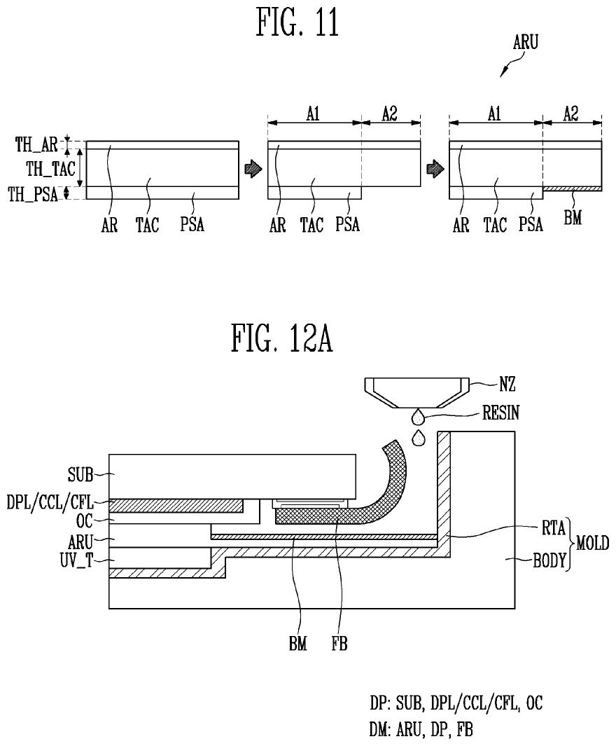

FIGS. 10 and 11 are schematic diagrams illustrating a method of manufacturing the optical layer included in the display module of FIG. 8.

Referring to FIGS. 8 to 11, the optical layer ARU may include an anti-reflection layer AR, a support layer TAC, and an adhesive layer PSA.

The anti-reflection layer AR may be a thin film for reducing reflection of external light, and may include a polarization film and/or a retardation film. A thickness TH_AR of the anti-reflection layer AR may be about 12 μm.

The support layer TAC may be disposed under or below the anti-reflection layer AR, and may support or protect the anti-reflection layer AR of a form of a thin film. For example, the support layer TAC may be implemented as a tri-acetyl-cellulose (TAC) film, and a thickness TH_TAC of the support layer TAC may be about 60 μm.

The adhesive layer PSA may be disposed under or below the support layer TAC and may include an adhesive material. For example, the adhesive layer PSA may be implemented as a pressure sensitive adhesive (PSA), and may couple or connect the optical layer ARU to the display panel DP. For example, a thickness TH_PSA of the adhesive layer PSA may be about 20 μm.

As shown in FIG. 10, a step may be formed in the optical layer ARU by removing a portion of the adhesive layer PSA and the support layer TAC corresponding to the second area A2 of the optical layer ARU. For example, a portion of the adhesive layer PSA and the support layer TAC corresponding to the second area A2 of the optical layer ARU may be removed through a laser, an etching process (for example, an etching process using plasma), or the like within the spirit and the scope of the disclosure. Thereafter, the light blocking pattern BM may be formed under or below the second area A2 of the optical layer ARU. For example, the light blocking pattern BM may be formed through printing, painting, anodizing, or the like within the spirit and the scope of the disclosure.

By attaching the optical layer ARU formed through the method of FIG. 10 to the display panel DP, the display module DM of FIG. 8 may be manufactured.

Even though a portion of the support layer TAC is removed in the second area A2 of the optical layer ARU, a function of the support layer TAC may be supplemented by the upper protective layer CRD (refer to FIG. 9). Even though the adhesive layer PSA corresponding to the second area A2 of the optical layer ARU is removed, the second area A2 of the optical layer ARU may be coupled or connected to the display panel DP by the upper protective layer CRD.

In FIG. 10, a portion of the support layer TAC corresponding to the second area A2 of the optical layer ARU is removed, but the disclosure is not limited thereto. In an embodiment, as shown in FIG. 11, in the second area A2 of the optical layer ARU, only the adhesive layer PSA may be partially removed, and the support layer TAC may not be removed. For example, in case that the thickness TH_OC of the overcoat layer OC shown in FIG. 8 is relatively large (for example, about 50 μm), or the difference between the thickness TH_FB of the circuit board FB and the thicknesses TH_OC of the overcoat layer OC is in a range of about 20 μm to about 30 μm, in the second area A2 of the optical layer ARU, only the adhesive layer PSA may be partially removed, and thus a step may be formed on the lower surface of the optical layer ARU.

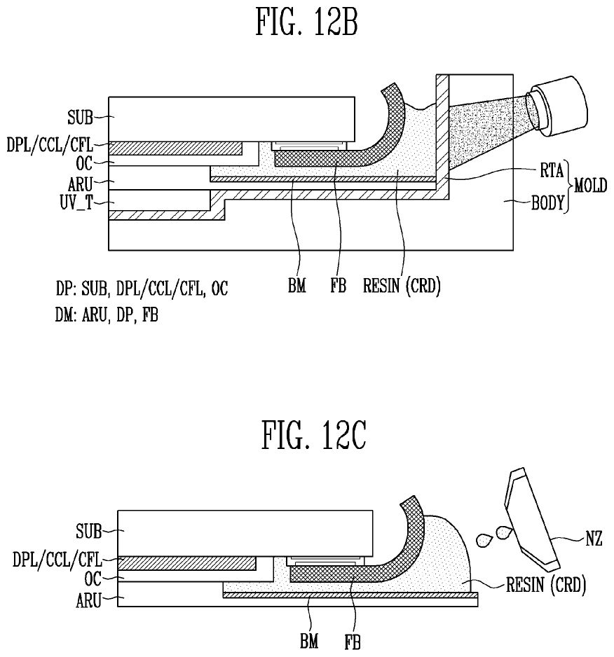

FIGS. 12A, 12B, and 12C are schematic diagrams illustrating a method of manufacturing the display module of FIG. 9.

In the specification, a manufacturing step of the display device DD is sequentially performed according to a cross-sectional view, however, some steps shown as being successively performed may be simultaneously performed, a sequence of each step may be changed, some steps may be omitted, or another step may be further included between each step within the spirit and the scope of the disclosure.

Referring to FIGS. 8 to 10, 12A, and 12B, the optical layer ARU may be attached to the display panel DP to cover or overlap the circuit board FB, and thus the display module DM of FIG. 8 may be manufactured.

Thereafter, the display module DM of FIG. 8 may be disposed or mounted on a mold MOLD. In a state in which the display module DM of FIG. 8 is flipped upside down, the display module DM may be disposed in the mold MOLD.

The mold MOLD may include a body portion BODY and a surface portion RTA. Pating treatment may be performed on the surface portion RTA to allow the display module DM to be readily separated from the mold MOLD. The mold MOLD may be formed of a transparent material (for example, glass) for transmitting light, but is not limited thereto.

The mold MOLD may include a bottom portion that is in contact with the display module DM and a sidewall portion protruding upward from one end or an end of the bottom portion. A shape of the sidewall portion may correspond to a shape of the upper protective layer CRD of FIG. 12B.

After the display module DM is disposed on the mold MOLD, as shown in FIG. 12A, a printing device may be positioned on the circuit board FB. The printing device may include a nozzle NZ. The printing device may store a resin solution RESIN of a liquid form and may supply the resin solution RESIN through the nozzle NZ.

The printing device may supply the resin solution RESIN to a space between the circuit board FB and the mold MOLD (for example, a sidewall of the mold MOLD adjacent to the circuit board FB) through the nozzle NZ. A distance between the substrate SUB and the mold MOLD (or the sidewall of the mold MOLD) may be about 1 mm. The resin solution RESIN may have a viscosity (centipoises) within a range of about 10 cps to about 100 cps. The resin solution RESIN may horizontally move through a gap between the circuit board FB and the optical layer ARU, and may be filled in or applied to the space between the optical layer ARU and the display panel DP (and the circuit board FB). The resin solution may be pressurized using a separate compression device so that the resin solution RESIN is filled in the space between the optical layer ARU and the display panel DP (and the circuit board FB).

Thereafter, as shown in FIG. 12B, light such as ultraviolet light or infrared light may be irradiated to the resin solution RESIN (for example, the resin solution RESIN applied in the mold) using a light source device. In order to prevent light from entering the display area in the display module DM in a process of irradiating the light, an ultraviolet blocking tape UV_T may be disposed so as to overlap a portion (for example, the overcoat layer OC) of the display module DM. The light-curable resin solution RSEIN may be cured to form the upper protective layer CRD. The circuit board FB and the display panel DP may be bonded to each other by the upper protective layer CRD, and the optical layer ARU and the circuit board FB may be coupled or connected to each other.

In FIG. 12B, the light source device is used, but the disclosure is not limited thereto. For example, in case that the resin solution RESIN is thermosetting, the resin solution RESIN may be heated and pressurized using a heating device instead of the light source device.

The lower protective layer CFD (refer to FIG. 9) may be formed through a method identical or similar to the method of forming the upper protective layer CRD, and the upper protective layer CRD and the lower protective layer CFD may be simultaneously formed.

Thereafter, by separating the display module DM from the mold MOLD, the display module DM of FIG. 9 may be finally formed.

In FIGS. 12A and 12B, the display module DM is manufactured using the mold MOLD, but the disclosure is not limited thereto.

In an embodiment, as shown in FIG. 12C, the nozzle NZ of the printing device may be positioned on one side or a side of the inverted display module DM, and the resin solution RESIN may be supplied and applied in an oblique direction from the nozzle NZ. Thereafter, the upper protective layer CRD may be formed by curing the resin solution RESIN using a light source device, a heating device, or the like within the spirit and the scope of the disclosure. For example, the upper protective layer CRD may be formed using a side sealing method instead of a sealing method using a mold.

As described above, the upper protective layer CRD may be formed by filling the resin solution RESIN in the space between the optical layer ARU and the circuit board FB (and the display panel DP) and curing the resin solution RESIN. In a state in which the optical layer ARU is disposed to cover or overlap the display panel DP and the circuit board FB (also in a state in which the optical layer ARU is supported by the mold MOLD), the upper protective layer CRD may be formed, and the upper protective layer CRD may support the optical layer ARU. Therefore, the display module DM formed through the above-described manufacturing method may have a highly planarized surface (for example, the optical layer ARU entirely planarized on the overcoat layer OC and the circuit board FB).

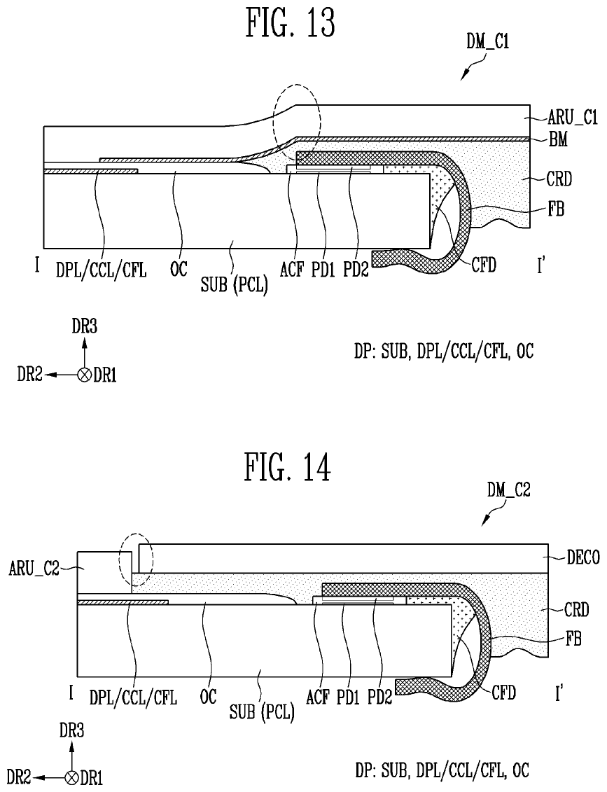

FIGS. 13 and 14 are schematic cross-sectional views illustrating a comparative embodiment of a display module taken along line I˜I′ of FIG. 2.

First, referring to FIGS. 9 and 13, since a display module DM_C1 of FIG. 13 is substantially the same as or similar to the display module DM of FIG. 9 except for an optical layer ARU_C1, a repetitive description is omitted.

The display module DM_C1 may include the optical layer ARU_C1.

A thickness of the optical layer ARU_C1 may be entirely constant. For example, the thickness of the optical layer ARU_C1 may be the same as the first thickness TH1 of the first area A1 of the optical layer ARU shown in FIG. 9. In case that the optical layer ARU_C1 is disposed to cover or overlap the overcoat layer OC and the circuit board FB, a step may occur on an upper surface of the optical layer ARU_C1. This is because the thickness of the circuit board FB is greater than the thickness of the overcoat layer OC. For example, the step may occur on the upper surface of the optical layer ARU_C1 in a portion corresponding to an edge of the circuit board FB.

In case that the upper protective layer CRD is formed by the method described with reference to FIGS. 12A to 12C, the upper protective layer CRD may not be formed in a space between the optical layer ARU_C1 and the display panel DP. This is because the circuit board FB and the optical layer ARU_C1 are in contact with each other and thus a gap is not formed between the optical layer ARU_C1 and the circuit board FB.

In order to form a gap between the optical layer ARU_C1 and the circuit board FB, the thickness of the overcoat layer OC may be set to be greater than the thickness of the circuit board FB, however, in this example, a thickness of the display module DM_C1 may be increased.

Referring to FIGS. 9 and 14, since a display module DM_C2 of FIG. 14 is substantially the same as or similar to the display module DM of FIG. 9 except for an optical layer ARU_C2 and a deco film DECO, a repetitive description is omitted.

The display module DM_C2 may include the optical layer ARU_C2 and the deco film DECO.

The optical layer ARU_C2 may partially overlap the overcoat layer OC and may not overlap the circuit board FB. In order to prevent the step from occurring on the upper surface of the optical layer ARU_C1 described with reference to FIG. 13, the optical layer ARU_C2 may be disposed to cover or overlap only a portion of the display panel DP. The circuit board FB may be exposed by the optical layer ARU_C2.

The deco film DECO (or a chassis) may be disposed on a portion of the display panel DP and the circuit board FB exposed by the optical layer ARU_C2. The deco film DECO may prevent the circuit board FB from being viewed.

As shown in FIG. 14, since the deco film DECO is not integral with the optical layer ARU_C2, due to a process error, the deco film DECO may be spaced apart from the optical layer ARU_C2. A height of an upper surface of the deco film DECO may be different from a height of an upper surface of the optical layer ARU_C2.

As described with reference to FIGS. 12A to 12C, the upper protective layer CRD may be formed in a state in which the optical layer ARU_C2 is coupled or connected to the display panel DP. After the upper protective layer CRD is formed, the deco film DECO may be disposed on the upper protective layer CRD. In a process of disposing the deco film DECO on the upper protective layer CRD, the deco film DECO may not be in close contact with the upper protective layer CRD. As described above, due to various errors caused by manufacturing equipment and material, a boundary portion between the deco film DECO and the optical layer ARU_C2 may be viewed, or a step may occur between the deco film DECO and the optical layer ARU_C2.

The optical layer ARU described with reference to FIGS. 8 and 9 may be disposed to cover or overlap the display panel DP and the circuit board FB, and the thickness of the second area A2 of the optical layer ARU overlapping the circuit board FB may be relatively small. Accordingly, a step may not occur on the upper surface of the optical layer ARU. The upper protective layer CRD may be filled in the entire space between the optical layer ARU and the display panel DP through the gap between the second area A2 of the optical layer ARU and the circuit board FB, external water, moisture, and the like may be blocked from proceeding to the inside of the display panel DP.

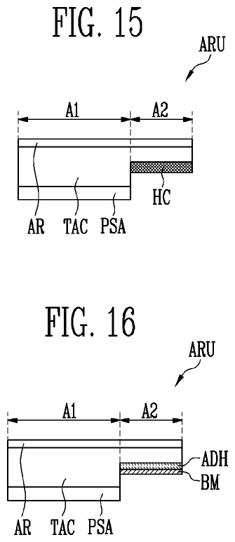

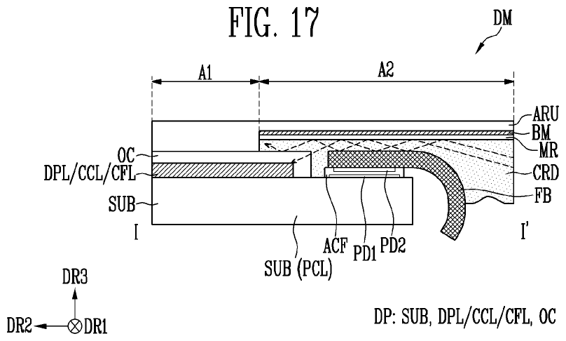

FIGS. 15 and 16 are schematic diagrams illustrating an embodiment of the optical layer included in the display module of FIG. 8.

Referring to FIGS. 8 to 11, 15 and 16, since the optical layer ARU of FIGS. 15 and 16 is substantially the same as or similar to the optical layer ARU of FIGS. 10 and 11, a repetitive description is omitted.

As shown in FIG. 15, a reinforcing layer HC (or a reinforcing member) may be further disposed on a lower surface of the second area A2 of the optical layer ARU.

The reinforcing layer HC may reinforce the relatively thin support layer TAC in the second area A2. The reinforcing layer HC may include an inorganic layer and/or an organic layer, and may be provided as a single layer or a multilayer. The reinforcing layer HC may be formed or stacked by a coating method. For example, the reinforcing layer HC may be formed through a hard coating and may have strength higher than that of the support layer TAC.

In an embodiment, the reinforcing layer HC may absorb an external impact. To this end, the reinforcing layer HC may include a material having a high impact absorption rate. For example, the reinforcing layer HC may include a polymer resin, for example, polyurethane, polycarbonate, polypropylene, polyethylene, and the like, but is not limited thereto.

The reinforcing layer HC may be disposed on or directly disposed under or below the support layer TAC or may be disposed under or below the light blocking pattern BM of FIG. 10. In case that the supporting layer TAC is not removed as shown in FIG. 11, the reinforcing layer HC may be omitted.

As shown in FIG. 16, the light blocking pattern BM may be implemented as a separate film, and may be coupled or connected to the support layer TAC of the optical layer ARU through an adhesive member ADH. However, the disclosure is not limited thereto. As described with reference to FIGS. 8 and 10, the light blocking pattern BM may include a ceramic, a metal, an organic layer, and/or an inorganic layer, and may be formed through printing, painting, anodizing, or the like within the spirit and the scope of the disclosure.

FIG. 17 is a schematic cross-sectional view illustrating an embodiment of the display module taken along line I˜I′ of FIG. 2.

Referring to FIGS. 9 and 17, since the display module DM of FIG. 17 is substantially the same as or similar to the display module DM of FIG. 9 except for a reflective layer MR, a repetitive description is omitted.

The optical layer ARU (or the display module DM) may further include the reflective layer MR (or a mirror surface). The reflective layer MR may be disposed under or below the light blocking pattern BM in the second area A2 of the optical layer ARU. In other words, the reflective layer MR may be disposed between the light blocking pattern BM and the upper protective layer CRD.

The optical layer ARU may reflect light transmitted through the upper protective layer CRD. For example, as described with reference to FIG. 12B, in case that ultraviolet light for curing the upper protective layer CRD is irradiated, the ultraviolet light may be reflected by the reflective layer MR and proceed to the inside of the display module DM (for example, to the first area A1 of the optical layer ARU). A portion of the upper protective layer CRD positioned between the overcoat layer OC and the optical layer ARU may also be completely cured or the upper protective layer CRD may be formed faster.

In an embodiment, the reflective layer MR may include a material having a constant reflectance, for example, the reflective layer MR may include an opaque metal. According to an embodiment, a surface of the reflective layer MR may have a concave-convex structure for diffuse reflection so that light proceeds to the inside of the display module DM.

According to an embodiment, the reflective layer MR may be further formed on one surface or on a surface of the circuit board FB that is in contact with the upper protective layer CRD.

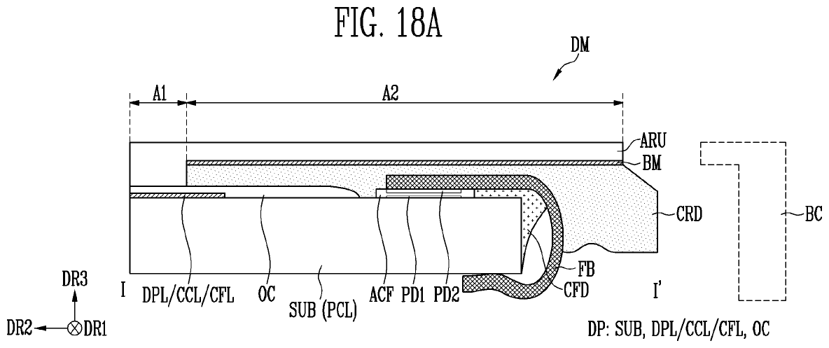

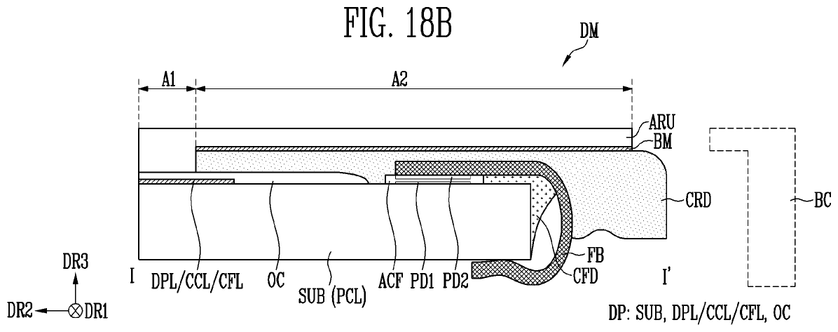

FIGS. 18A and 18B are schematic cross-sectional views illustrating an embodiment of the display module taken along line I˜I′ of FIG. 2.

Referring to FIGS. 9, 18A, and 18B, since the display module DM of FIGS. 18A and 18B is substantially the same as or similar to the display module DM of FIG. 9 except for a shape of the upper protective layer CRD, a repetitive description is omitted.

A side surface (or an outer surface) of the upper protective layer CRD may have various shapes corresponding to a shape of a sidewall of the accommodation member BC.

For example, as shown in FIG. 2, in case that the sidewall of the accommodation member BC is perpendicular in the third direction DR3, the side surface of the upper protective layer CRD may coincide with an end of the optical layer ARU (refer to FIG. 9). In other words, the side surface and an upper surface of the upper protective layer CRD may have a right angle.

For example, in case that an upper end of the sidewall of the accommodation member BC has a shape protruding inward (for example, in the second direction DR2), the side surface (or a corner portion where the side surface and the upper surface of the upper protective layer CRD are in contact with each other) may have an inclined surface (refer to FIG. 18A) or a curved surface (or a round) (refer to FIG. 18B).

For example, the upper protective layer CRD may have a shape that protrudes outward from the optical layer ARU. A width at which the upper protective layer CRD protrudes outward from the optical layer ARU (for example, a width in the second direction DR2) may be equal to a width at which the upper end of the sidewall of the accommodation member BC protrudes inward. The side surface or a side surface of the upper protective layer CRD may be in close contact with the sidewall of the accommodation member BC. Therefore, structure reliability of the display module DM may be improved.

The upper protective layer CRD shown in FIGS. 18A and 18B may be formed by changing a shape of a corner portion where the bottom portion and the sidewall portion of the mold MOLD of FIG. 12A are in contact with each other.

Although the disclosure has been described in detail in accordance with the above-described embodiments, it should be noted that the above-described embodiments are for the purpose of description and not of limitation. Those skilled in the art will understand that various modifications are possible within the scope of the disclosure.

The scope of the disclosure is not limited to the details described in the detailed description of the specification, but should also be defined by the claims. It is to be understood that all changes or modifications derived from the meaning and scope of the claims and equivalents thereof are included in the scope of the disclosure.

What is claimed is:

1. A display device comprising:
a display panel including pixels disposed in a display area and a non-display area adjacent to at least a side of the display area;
a circuit board bonded to at least a surface of the display panel that overlaps the non-display area in a plan view, the circuit board being electrically connected to the pixels; and
an optical layer disposed on the display panel, wherein the optical layer includes:
a first region having a first thickness; and
a second region having a second thickness less than the first thickness of the first region of the optical layer, and
the second region of the optical layer overlaps the bonded portion of the circuit board in a plan view.

2. The display device according to claim 1, further comprising:
a light blocking pattern disposed on a surface of the optical layer facing the circuit board in the second region of the optical layer.

3. The display device according to claim 2, wherein the light blocking pattern is at least one of a printed light blocking pattern, painted light blocking pattern, and anodized light blocking pattern.

4. The display device according to claim 2, wherein the light blocking pattern includes at least one of a ceramic, a metal, an organic layer, and an inorganic layer.

5. The display device according to claim 1, wherein a surface of the optical layer facing the circuit board in the second region of the optical layer includes a step.

6. The display device according to claim 5, wherein the step of the optical layer is a lasered portion or an etched portion of the second region of the optical layer.

7. The display device according to claim 5, wherein the optical layer comprises:
an anti-reflection layer;
a support layer disposed below the anti-reflection layer that supports the anti-reflection layer; and
an adhesive layer disposed below the support layer,
wherein the adhesive layer is removed in the second region of the optical layer.

8. The display device according to claim 7, wherein a portion of the support layer is removed in the second region of the optical layer.

9. The display device according to claim 8, wherein the optical layer comprises a reinforcing layer disposed below the support layer in the second region of the optical layer.

10. The display device according to claim 9, wherein the reinforcing layer is a hard-coated reinforcing layer and absorbs an external impact applied to the optical layer.

11. The display device according to claim 1, further comprising:
a protective layer disposed between the circuit board and the second region of the optical layer and covering a portion of the circuit board and the display panel.

12. The display device according to claim 11, wherein the protective layer includes a resin between the circuit board and the second region of the optical layer.

13. The display device according to claim 11, further comprising:
a reflective layer disposed between the optical layer and the protective layer in the second region of the optical layer.

14. The display device according to claim 11, wherein the protective layer protrudes outward from the second region of the optical layer in a plan view.

15. The display device according to claim 1, wherein the second region of the optical layer protrudes outward from the display panel in a plan view.

16. The display device according to claim 1, wherein the display panel comprises:
a display element layer including a light emitting element; and
a light conversion pattern layer disposed on the display element layer and changing a wavelength of light emitted from the light emitting element using a quantum dot, and
the light conversion pattern layer is formed through a successive process on a base surface provided by the display element layer.

17. The display device according to claim 16, wherein the light emitting element includes an inorganic light emitting diode.

18. A method of manufacturing a display device, the method comprising:
attaching an optical layer to a display panel to cover a circuit board bonded to at least a surface of the display panel;
applying a resin solution between the optical layer and the display panel through a gap between the optical layer and the circuit board; and
forming a protective layer between the optical layer and the circuit board by curing the resin solution, wherein
the optical layer includes:
a first region having a first thickness; and
a second region having a second thickness less than the first thickness of the first region of the optical layer, and
the second region of the optical layer overlaps the bonded portion of the circuit board in a plan view.

19. The method according to claim 18, wherein
the optical layer comprises:
an anti-reflection layer;
a support layer disposed below the anti-reflection layer to support the anti-reflection layer; and
an adhesive layer disposed below the support layer, and
the adhesive layer is removed in the second region of the optical layer.

20. The method according to claim 19, wherein a portion of the support layer is removed in the second region of the optical layer.
